(19) United States
(12) Patent Application Publication
(10) Pub. No.: US 2024/0184957 A1
(43) Pub. Date: Jun. 6, 2024

(54) SYSTEMS AND METHODS FOR FRACTURE-PATTERN PREDICTION WITH RANDOM MICROSTRUCTURE USING PHYSICS-INFORMED DEEP NEURAL NETWORKS

(71) Applicant: Yongming Liu, Chandler, AZ (US)

(72) Inventor: Yongming Liu, Chandler, AZ (US)

(73) Assignee: Arizona Board of Regents on Behalf of Arizona State University, Tempe, AZ (US)

(21) Appl. No.: 18/223,378

(22) Filed: Jul. 18, 2023

Related U.S. Application Data
(60) Provisional application No. 63/368,687, filed on Jul. 18, 2022.

(51) Int. Cl. G06F 30/27

(52) U.S. Cl. CPC G06F 30/27

(57) ABSTRACT

Material fracture is a process involving both linear elastic stage and nonlinear crack propagation stage. A system includes a physics-informed deep learning model integrated with a discrete simulation model (lattice particle method-LPM) to predict material fracture patterns for arbitrary material microstructures under different loadings. The key idea is to leverage physics-knowledge and data-driven approach for accurate and efficient nonlinear mapping. Physics-knowledge includes constraints, microstructure images, and displacement field from pure linear elastic analysis in a linear stage. A Fully Convolutional Network predicts the final fracture patterns in a non-linear stage. The system exhibits high computational efficiency for the nonlinear stage of material response prediction.

### CROSS REFERENCE TO RELATED APPLICATIONS

This is a non-provisional application that claims benefit to U.S. Provisional Application Ser. No. 63/368,687, filed on Jul. 18, 2022, which is herein incorporated by reference in its entirety.

### FIELD

The present disclosure generally relates to material fracture analysis, and in particular, to a system and associated method for computer-implemented fracture pattern prediction with random microstructures using physics-informed neural networks.

### BACKGROUND

Material fracture failure is a critical issue for many engineering structures and components. Accurate fracture prediction is necessary to ensure the safety of these structures and components. The finite element method (FEM) is the most widely used approach for material mechanical modelling. FEM is known to have difficulties to solve problems involving spatial discontinuities, such as fracture and material interface. Lattice particle method (LPM) is a recently developed discrete approach. Both local pair-wise potential and non-local multi-body potential are included in LPM. Due to the intrinsic characteristics of integro-differential governing equations in LPM, it is naturally suitable for discontinuous problems. The development of LPM focused on linear elastic material initially and can simulate brittle material fractures including for heterogenous materials and composite materials. LPM has been applied in the past for ductile material simulation using orthogonal dilatational and distortional energy decomposition.

Material fracture simulation intrinsically includes both linear elastic state and nonlinear crack propagation stage. In order to solve nonlinear problems, integration of the incremental algorithms with LPM is needed, i.e., LPM tracks nonlinear deformation using many time steps and iterations. Therefore, the incremental method demands a high computational cost. A large number of particles is usually required in LPM to obtain accurate fracture simulation, which makes the LPM simulation time-consuming.

It is with these observations in mind, among others, that various aspects of the present disclosure were conceived and developed.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1E are a series of illustrations showing lattice packing arrangements for modeling material mechanics using Lattice Particle Method (LPM);

FIG. 2 is an illustration showing an example of a fully convolutional network (FCN);

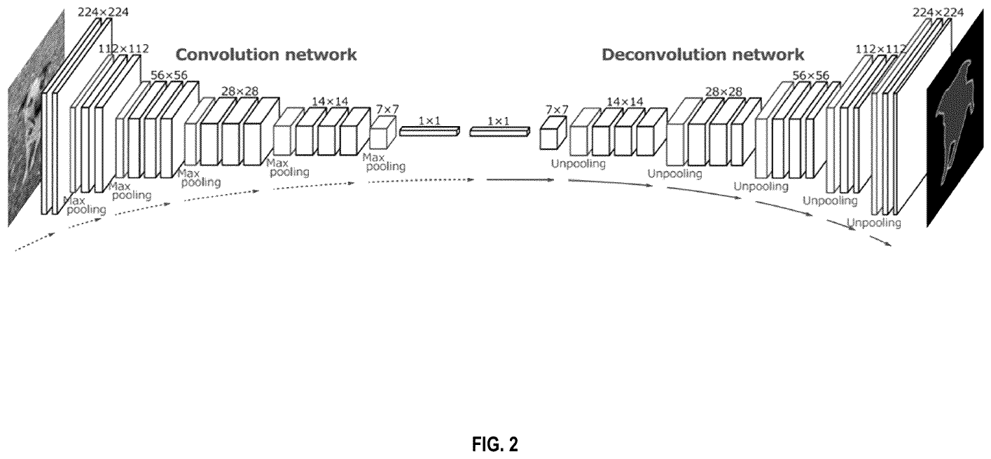

FIG. 3 is a simplified diagram showing a system that includes a physics-informed model for modeling material mechanics;

FIG. 4 is a simplified diagram showing a loading configuration for investigating fracture patterns in 2-dimensional representative volume elements (RVEs);

FIGS. 5A-5C are a series of illustrations showing microstructures and corresponding fracture patterns;

FIG. 6 is a simplified schematic diagram showing an architecture of an FCN for modeling fracture patterns using the system of FIG. 3;

FIG. 7 is a process flow showing an LPM scheme for modeling fracture patterns using the system of FIG. 3;

FIG. 8 includes a series of images showing loss history of training and testing datasets;

FIG. 9 is a graphical representation showing predictions of the deep learning model implemented by the system of FIG. 3 with corresponding microstructures and truths;

FIG. 10 includes a series of images showing F1 score history of training and testing datasets;

FIG. 11 is a graphical representation showing an example of F1 score calculation implemented by the system of FIG. 3 without max-pooling operations;

FIG. 12 includes a series of images showing F1 score calculation after a max-pooling operation;

FIGS. 13A-13C are a series of graphical representations showing F1 score history of training and testing datasets with and without max-pooling and with respect to a ground truth dataset;

FIGS. 14A-14C are a series of graphical representations showing loss history of a data-driven model and a physics-informed model and with respect to a ground truth dataset;

FIG. 15 is a graphical representation showing F1 score of a data-driven model and a physics-informed model with and without max-pooling;

FIG. 16 is a graphical representation showing model loss displaying a physical constraint effect shown by F1 scores for a data-driven model and a physics-informed model;

FIG. 17 is a graphical representation showing F1 scores for a fracture patterns under different loadings with the same microstructure for a data-driven model and a physics-informed model; and

FIG. 18 is a simplified diagram showing an exemplary computing system for implementation of the system of FIGS. 3 and 6.

Corresponding reference characters indicate corresponding elements among the view of the drawings. The headings used in the figures do not limit the scope of the claims.

### DETAILED DESCRIPTION

### 1. Introduction

The present disclosure provides systems and methods for modeling material mechanics, particularly fracture patterns, using deep learning methods for applying Lattice Particle Method (LPM) with the goal of reducing computational time. In the past decade, deep learning has been successfully used in many complex analyses, such as computer vision, natural language processing (NLP), and system control. Deep learning has also been used by materials and mechanics scientists for material reconstruction and material property prediction. For material fracture problems, most researchers have applied deep learning to predict fracture parameters, such as fracture energy and stress intensity factor (SIF). Very few works have been done to predict fracture patterns using deep learning. Only a handful of research projects in this field have been related to fracture pattern prediction, which includes fracture's spatial information. One such example simulated fracture crack propagation for both mode I and mode II loading conditions with an initial crack. Another example predicted collision fracture patterns on a disk. Both these two works used convolutional neural networks (CNNs), an algorithm of deep learning suitable for image processing.

A system for modeling material mechanics disclosed herein has two significant novelties compared with the above-mentioned studies. First, the system incorporates heterogeneous random microstructure information; the existing studies are for homogeneous materials. Random microstructure effect promotes random crack initiation and crack patterns, which is more challenging to predict. Second, existing studies are purely data-driven approaches, and they need numerous training data to achieve accurate predictions. The system can be tuned using less training data and fewer training epochs. This is achieved by leveraging physics knowledge from constraints and linear elastic responses in the system. It should be noted that the linear elastic response of materials usually has universal agreement among researchers and is very fast to compute. Nonlinear fracture simulation usually does not have universal agreement among researchers (e.g., different crack initiation and propagation criteria) and is very time consuming to compute. Thus, the system aims for a nonlinear part for fracture simulation.

Inspired by the above-mentioned discussions, the system implements a physics-informed model to predict fracture patterns for arbitrary geometries and loading conditions, which is an integration of an efficient deep learning model and LPM. LPM and deep learning model have different advantages for different stages in fracture simulations. The key idea is that the elastic deformation in linear stage is computed as physics knowledge and then is taken in by a deep learning model. Compared with LPM, a deep learning model is more efficient for nonlinear crack simulation. For the linear elastic stage, LPM has very good computational efficiency for the linear stage. Thus, the system combines LPM (linear stage) and a deep learning model (nonlinear stage) for material fracture pattern prediction. With this integration, computational accuracy and efficiency are both considered. LPM is used in this context to: 1) simulate material elastic deformation in the linear stage as input for the deep learning model implemented by the system; and 2) generate a training dataset of fracture pattern.

The remainder of this disclosure is organized as follow: First, a brief review of LPM formulation and a CNN algorithm is presented in Section 2. Following this, the details of the system that combines LPM and a deep neural network are provided Section 3. Next, model implementation and experimental results are shown in Section 4. In Section 5, the effects of physics knowledge and loading are discussed. In Section 6, some conclusions are drawn.

### 2. Background

### 2.1 Lattice Particle Method

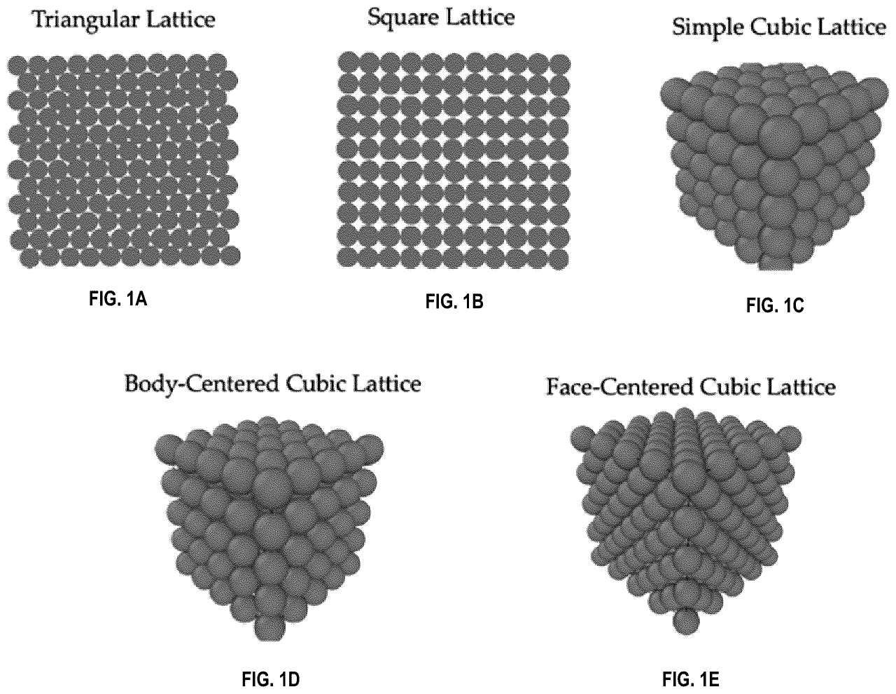

LPM formulation depends on the lattice structure used to discretize the solution domain. Various lattice structures have been employed in LPM, such as triangular and square lattice structures for two-dimensional analysis, and simple cubic, body-centered cubic and face-centered cubic lattice structures for three-dimensional analysis, as shown in FIGS. 1A-1E.

In LPM, a typical particle can interact with neighboring particles and remote particles depending on how many layers of particles is involved in the interaction distance. For a given interaction distance, unit cell is identified for each type of neighbor. And the potential energy for a particle is the summation of the energy associated with these unit cells. For each unit cell, the stored energy can be separated into two parts, a local pairwise energy corresponding to the stretch between two particles and a non-local multi-body energy associated with its volume change. For particle I, the stored energy in one of its unit cell can be written as:

$${U}_{I}^{nonlocal} = \frac{1}{2} {T}_{I} = {( {\sum }_{J = 1}^{{N}_{I}} δ {l}_{IJ} )}^{2} \qquad ( 1 )$$

with the local energy U_{I}^{local} can be expressed in terms of distance change between particle I and its neighbors for current unit cell as:

$${U}_{I}^{local} = \frac{1}{2} {\sum }_{J = 1}^{{N}_{I}} {{k}_{IJ} ( δ {l}_{IJ} )}^{2} \qquad ( 2 )$$

and the nonlocal energy U_{I}^{nonlocal} for current unit cell is calculated as:

$${U}_{I}^{nonlocal} = \frac{1}{2} {T}_{I} = {( {\sum }_{J = 1}^{{N}_{I}} δ {l}_{IJ} )}^{2} \qquad ( 3 )$$

In Equations. (2) and (3), k_{IJ} is the local parameter for each pair of interacting particles, T_{I} is the nonlocal parameter, δl_{IJ} is the distance change between particle I and its neighbor J, N_{I} is the total number of neighboring particles interacting with particle I for current unit cell.

Equating the energy of a particle in LPM to its continuum equivalent, the material stiffness tensor can be obtained by the theory of hyperelasticity as:

$${C}_{ijkl} = \frac{1}{{V}_{I}} \frac{{\partial }^{2} Σ {U}_{I}}{\partial {ε}_{ij} \partial {ε}_{kl}} \qquad ( 4 )$$

where εᵢⱼ is the strain tensor at a particle I.

For small deformation, the distance change between particles can be mapped to the strain tensor using following relationship:

$${ε}_{IJ} = \frac{δ {L}_{IJ}}{{L}_{IJ}} = {ε}_{ij} {n}_{ij} {n}_{j} \qquad ( 5 )$$

where L_{IJ} is the initial distance between particle I and its neighbor J, nᵢ and nⱼ are the components of unit vector connecting particle I and its neighbor J.

LPM parameters can be determined by comparing the material stiffness tensor given in Eq. (4) with generalized Hooke's relationship. Certain constraints need to be imposed between LPM parameters for different neighbors, such as k and T should be the same for the same type of neighbors for an isotropic material. For isotropic materials, the derived LPM parameters in terms of material constants for different lattice structures are given in Table 1.

Given the LPM parameters, the interaction between particle I and its neighbor J can be calculated by differentiating the total stored energy with respect to its distance change as:

$${f}_{IJ} = \frac{\partial {U}_{I}}{\partial δ {l}_{IJ}} = {n}_{IJ} . \qquad ( 6 )$$

In LPM, the equation of motion for a particle I at time t is given by:

$${m}_{I} {\ddot{\ddot{u}}}_{I} ( t ) = {\sum }_{J = 1}^{{N}_{I}} {f}_{IJ} ( t ) + {b}_{I} ( t ) ∀ ( I , t ) ∈ Ω x ( 0 , τ ) \qquad ( 7 )$$

where m is mass, u(t) is the displacement vector, ƒ_{IJ}(t) is the interaction force between particles I and J, and b_{I}(t) is external force vector.

### 2.2 Fully Convolutional Network

A L-layer deep neural network can be expressed as a function as:

TABLE 1
LPM parameters for isotropic material (R is the half origin distance with nearest
neighbor, E is Young's modulus, v is Poisson's Ratio).

| (using 1st and 2nd nearest | Local parameter | Nonlocal parameter |
|---|---|---|
| neighbors) | k (k1, k2) | T |
| Triangular lattice (only 1st nearest neighbor) | $k = \frac{4 E}{\sqrt{3} ( 1 + v )}$ | $T = \frac{E ( 3 v - 1 ) ( 1 - v )}{2 ( 1 + v ) {( 1 - 2 v )}^{2}}$ |
| Square lattice | $k 1 = \frac{2 E}{( 1 + v )} , k 2 = \frac{E}{( 1 + v )}$ | $T = \frac{E ( 4 v - 1 )}{2 ( 1 + v ) ( 1 - 2 v )}$ |
| Simple cubic lattice | $k 1 = \frac{2 E}{( 1 + v )} , k 2 = \frac{E}{( 1 + v )}$ | $T = \frac{RE ( 4 v - 1 )}{9 ( 1 + v ) ( 1 - 2 v )}$ |
| Face-centered cubic lattice | ${k}_{1} = \frac{2 \sqrt{3} RE}{1 + v} , {k}_{2} = \frac{2}{3} \frac{2 \sqrt{3} RE}{1 + v}$ | $T = \frac{\sqrt{2} RE ( 4 v - 1 )}{12 ( 1 + v ) ( 1 - 2 v )}$ |
| Body-centered cubic lattice | ${k}_{1} = \frac{2 \sqrt{3} RE}{1 + v} , {k}_{2} = \frac{2}{3} \frac{2 \sqrt{3} RE}{1 + v}$ | $T = \frac{\sqrt{2} RE ( 4 v - 1 )}{7 ( 1 + v ) ( 1 - 2 v )}$ |

y(x|W)=(σ^{L}W^{L}, . . . , σ²(W²,σ¹(W¹,x))) (8)

with parameters W={W¹, W², . . . , W^{L}} and input x. The function σ is called activation function, which acts on all components of the vector. During the training phase, the network weights are determined by minimizing the difference between network output and observations. It is found that, given enough nodes, neural networks with non-linear activation functions have the potential to approximate any complicated functions.

CNNs, an algorithm of deep neural networks, have achieved great success on image learning tasks in the computer vision domain. The strength of feature extraction gives CNNs enormous computational power when dealing with domain specific features. While the sharing of network parameters reduces the computational complexity without compromising feature extraction capabilities.

The development of CNNs originated from the competition of handwritten digit recognition in the early 90s. LeNet is one of the pioneering frameworks but the following research standstill for a while due to the computing power of computer hardware. AlexNet is credited as the first work in the field of computer vision with the significant advancement of computational capabilities and GPUs. AlexNet is much bigger than LeNet in considering the network size and achieved great improvement on image classification accuracy. The next milestone work is GoogLeNet architecture namely Inception-v1 that gives more network utilization with fewer parameters than AlexNet. Further refinement of the Inception model led to the newer version with the use of batch normalization. The universal use of a small 3×3 convolutional filter was first introduced in VGGNet to deal with the parameter exploding issue when adding the depth factor in CNNs. Deep residual learning is another milestone work where the layers can learn residual functions with respect to inputs. Deep residual learning is proved that is especially useful when training much deeper networks with much performance gain.

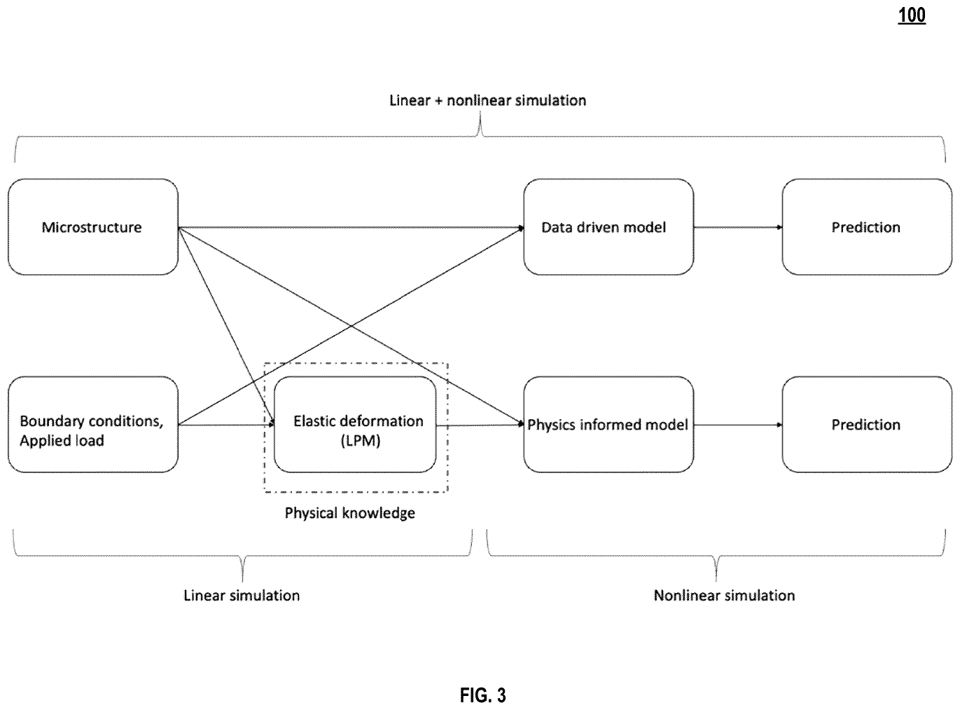

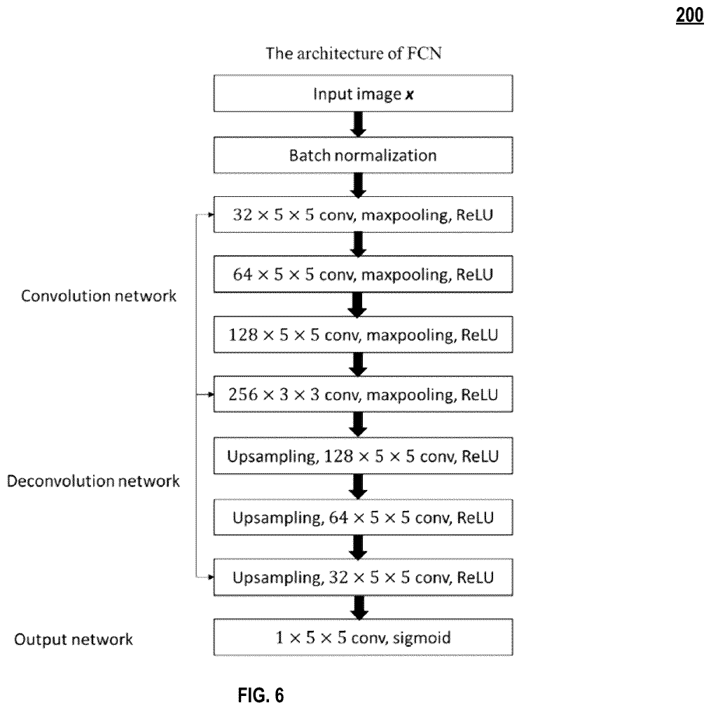

The system 100 is shown in FIG. 3 and implements the deep learning model for modeling a brittle material fracture process discussed herein. The system 100 uses a fully convolutional network (FCN) 200 shown in FIG. 6 to model a nonlinear stage of a brittle material fracture process. FCN 200 is a special type of convolution neural network (CNN), that only includes convolutional layers. CNNs are investigated to replace some fully connectional layers in a typical deep neural network with convolution layers, which take advantage of visual imagery. It can be seen that the outputs of FCNs are pixel-wise labeled images with the same revolution of inputs. This specialty allows FCNs to commonly be applied to semantic segmentation of images.

### 3. Proposed Model

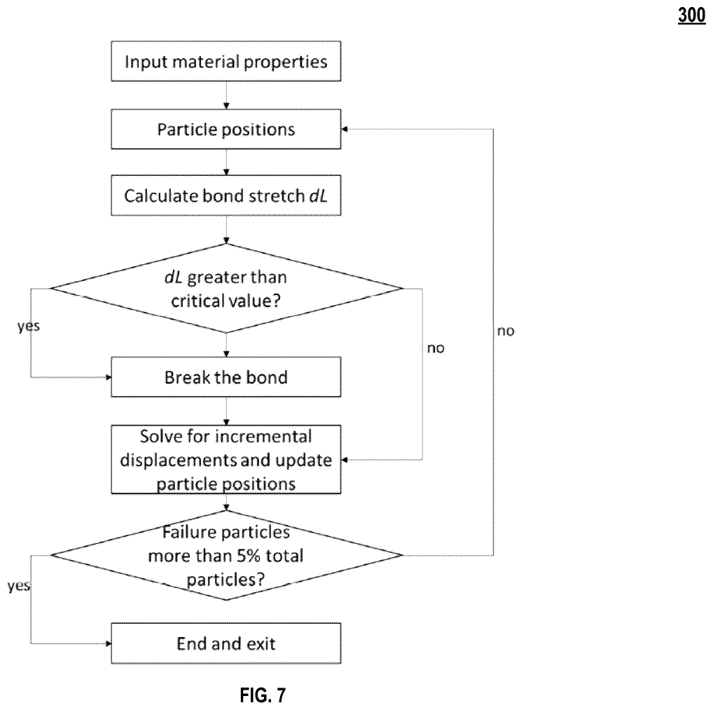

The system 100 implements a physics-informed model for the brittle material fracture process. Under a specific loading, the deformation of the material is linear elastic before occurrences of crack nucleation, and then with crack propagation, the deformation becomes nonlinear until fracture failure. For the nonlinear simulation, an incremental method is integrated with LPM to track the nonlinear process which brings a large number of iterations; therefore, the nonlinear simulation of LPM is time-consuming. Here, the present disclosure provides a surrogate way to utilize a deep learning model to replace LPM for nonlinear simulation, which allows the system 100 to predict the fracture process efficiently. The physical knowledge is the elastic deformation in linear stage computed by LPM (see FIG. 7). FIG. 3 shows the difference between a purely data driven model (top half) and the physics-informed model implemented by the system 100 (bottom half). LPM is used for a linear stage of the simulation and the FCN 200 shown in FIG. 6 is subsequently used for a nonlinear stage of the simulation.

### 3.1 Problem Statement

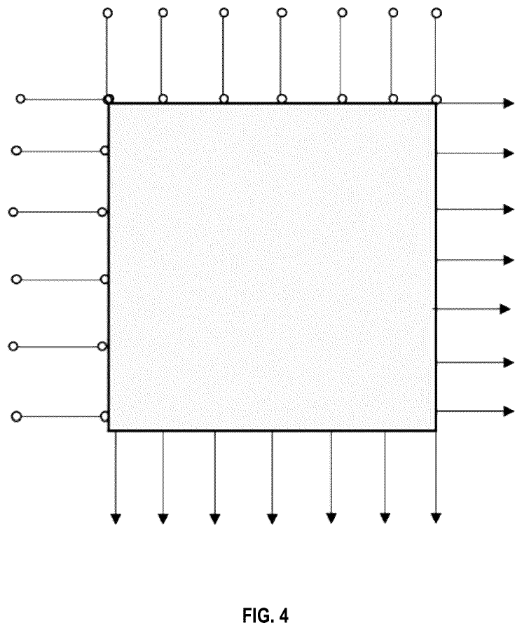

Fracture propagation is stochastic with random state of microstructure. The fracture pattern is often considered highly relating to material microstructures and loading conditions. Thus, one goal of the system 100 is to predict fracture patterns efficiently with given material microstructures and loading conditions. This disclosure investigates fracture patterns in two-dimensional representative volume elements (RVEs), with the dimension of 0.01 m by 0.01 m. FIG. 4 shows the loading conditions in this study. Top and left surfaces are fixed along vertical and horizontal axes, respectively, and the bottom and right surfaces are applied with uniformly distributed displacement-controlled loads in downward and rightward directions, respectively. The ratio of these two loads magnitudes is random, which introduces randomness of loading. For LPM simulation, specimens are loaded slowly such that quasi-static assumption is valid.

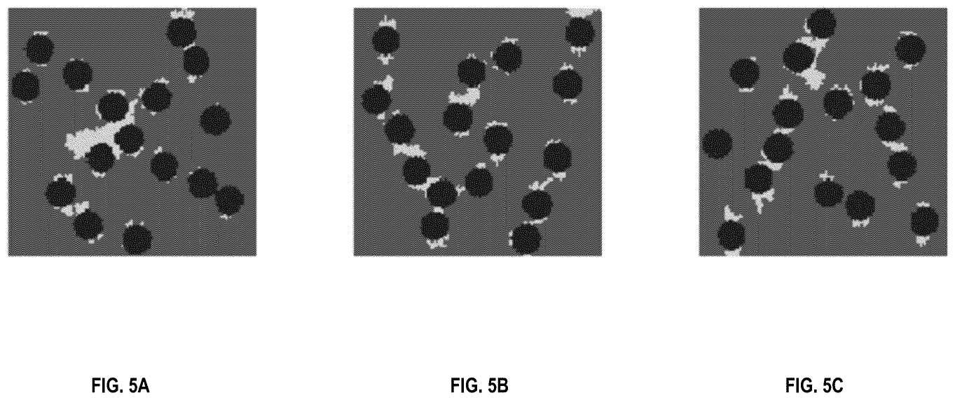

Some examples of stochastic microstructures and corresponding fracture patterns under uniaxial loads are shown in FIGS. 5A-5C. Maroon circles in microstructures represent holes in RVEs. It can be seen that the positions of holes are stochastic and the total number of holes in one RVE is a constant of 16. The radius of the holes are initially assigned at 0.0006 m and the system 100 avoids overlap of holes for RVEs generation. Fracture is represented in yellow color. The system 100 aims to predict fracture patterns using LPM and a deep neural network with a specific microstructure and a loading condition.

### 3.2 LPM for Fracture Simulation

In order to generate training data of fracture patterns and elastic deformation, a fracture criterion is implemented in LPM. Critical energy/force/elongation criteria can be derived based on different material properties, such as fracture toughness and material strength. In particular, the fracture criterion used in this disclosure are bond-based, in which the critical elongation is set as 0.45% bond length. Once the critical elongation is reached by a bond during the simulation step, the bond is considered broken and removed from future simulation steps. The entire fracture process can be tracked by the bond breaking process. A flowchart showing a process 300 for LPM fracture simulation as implemented by the system 100 is shown in FIG. 7. The process 300 can be performed in practice to model the linear stage of the fracture process, with outputs of the process 300 including a first set of data indicative of linear elastic deformation of the represented microstructure. The first set of data can be used as input to the fully convolutional network 200. Further, the process 300 for LPM fracture simulation can model the non-linear stage of the fracture process when generating a ground truth dataset for the fully convolutional network 200.

When trained, to model a fracture process of a represented microstructure, the system 100 models the linear stage of a fracture process of the represented microstructure using the lattice particle method (e.g., process 300) resulting in a first set of data indicative of linear elastic deformation of the represented microstructure. Following modeling of the linear stage through application of process 300, the fully convolutional network 200 models the non-linear stage of the fracture using the first set of data indicative of linear elastic deformation of the represented microstructure without needing to apply the process 300 for LPM fracture simulation. The result includes a probability of fracture failure of the represented microstructure. As such, the fully convolutional network 200 is a physics-informed model, having been trained on physics informed fracture simulations driven by the lattice particle method (e.g., process 300). This contrasts with purely data-driven models in which networks are trained on fracture data, which can be expensive and time-consuming to obtain ground truth data for.

In some embodiments, each RVE includes 26,187 particles, in which particle structure is triangular. The failure of particle is defined when the particle has broken bonds. Once the number of failure particles reaches 5% of the total number of particles, the material is considered to be fracture failure and then material fracture pattern is collected, where particle status is labeled as 1 or 0, representing failure or not failure.

### 3.3 The FCN Details

Fracture pattern prediction can be regarded as a task of semantic segmentation, which involves pixel-wise labeling to represent fracture failure or not. The proposed deep learning model implemented by the system 100 includes the FCN 200, in which data in the network can be operated as images. Input data is a three-dimensional array of size cⁱⁿ×h×w, where cⁱⁿ denotes channels number and h×w is image dimension. The size of output array is c^{out}×h×w, where image dimension is same as input. In our investigation, the input channel, cⁱⁿ, is three, which includes a binary image of microstructure and two displacement images in horizontal and vertical directions, respectively. The output channel number, c^{out}, is one, which only has one binary image of fracture pattern.

The FCN 200 includes three components: a convolution network, a deconvolution network, and an output network. The convolution network extracts features, and the deconvolution network labels pixels based on the features from the convolution network. A structure of the FCN 200 is shown in FIG. 6. For the FCN 200, a batch normalization layer normalizes input distribution to standard Gaussian distribution. The convolution network has convolutional layers of a fixed filter size (5×5) with ReLU activation functions. The ReLU function is expressed as,

ReLU(x)=max{0,x} (9)

After each convolutional layer, there are batch normalization layers and max-pooling layers. Each pooling layer is of stride 2, down-sampling these layers by a factor of 2 along both width and height. The deconvolution network consists of up-sample layers and convolution layers following batch normalization layers. In deconvolution networks, the up-sample method is bilinear interpolation with a factor of 2, and activation functions are ReLU. Because the output of the deep network is used for binary classification, the output network is a convolution layer with a logistic activation function of sigmoid. The sigmoid function in the output layer is given as,

$$signoid ( x ) = \frac{1}{1 + exp ( - x )} \qquad ( 10 )$$

The output from the FCN 200 is a probability of fracture failure, and the threshold is set to 0.5, i.e., the pixel is labeled as fracture failure if its output value is great than 0.5, otherwise, it is labeled as no fracture.

Training the FCN 200 involves minimizing a binary cross-entropy loss function is

$${L}_{BCE} = \frac{1}{N} {\sum }_{n = 1}^{N} {y}_{n} \cdot log ( p ( {y}_{n} ) ) + ( 1 - {y}_{n} ) \cdot log ( 1 - p ( {y}_{n} ) ) \qquad ( 11 )$$

where N is the total number of samples, yₙ represents label target, and p(yₙ) represents probability.

### 3.4 Physics Constraint on NN

There is a physical constraint in this problem that the fracture failure cannot occur in hole area, i.e., output pixels in hole area has zero probabilities of fracture failure. In order to improve the accuracy of the FCN 200, this physical constraint is applied following the output layer in the deep learning model by pixel-wise multiplying the microstructure array as:

y=T(x)·xₘ (12)

where y is the output after physical constraint, T is the function representing the proposed deep network, x is the input of the deep network, xₘ is the microstructure channel in the input. In the microstructure array, pixels in hole area are represented as zero, therefore, the output values of pixels in hole area are fixed to zero by the pixel-wise multiplication.

### 4. Experiments and Results

In this section, the system 100 was implemented using LPM and the deep learning model to predict fracture patterns. First, a dataset for the network training is generated by LPM. Then, the neural network is tuned with the training dataset. Next, the system 100 is evaluated in many aspects.

### 4.1 Model Training

LPM is carried out to simulate 900 fracture patterns of different RVEs under random loadings. Thereinto, 80% of them are used for model training, and 20% of them are testing data. To be compatible with the format of deep network implementation, all arrays from LPM simulations are converted to two-dimensional grids of size 128×128, based on the spatial coordinates corresponding to array elements, in which the nearest extrapolation method is used. The training dataset contains a binary array of RVEs' microstructures, two arrays of elastic deformations in horizontal and vertical directions, and a binary array of fracture patterns. The microstructures and elastic deformations arrays are inputs, and the fracture patterns are output targets.

During training, the model performance is evaluated on the testing dataset after each epoch. The detail of the accuracy metric used for evaluation is discussed in the next subsection. Given many epochs for model training, an overfitting phenomenon is found, i.e., the training accuracy metric is increasing while the testing accuracy metric is decreasing. To avoid it, an early stopping approach is adopted in which the training is stopped when the testing accuracy metric is smaller than its maximum value over ten epochs. For model tuning, the standard ADAM optimization algorithm and backpropagation are implemented in Pytorch. The learning rate for the ADAM optimizer was initialized to 0.0001 with a geometric decay rate of 0.9 and 0.999 for first and second moment estimates, respectively.

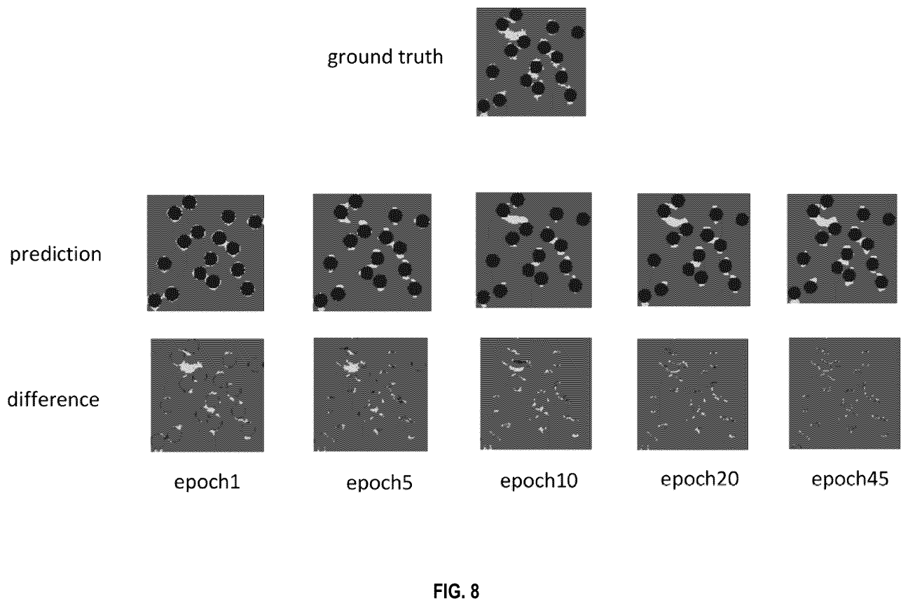

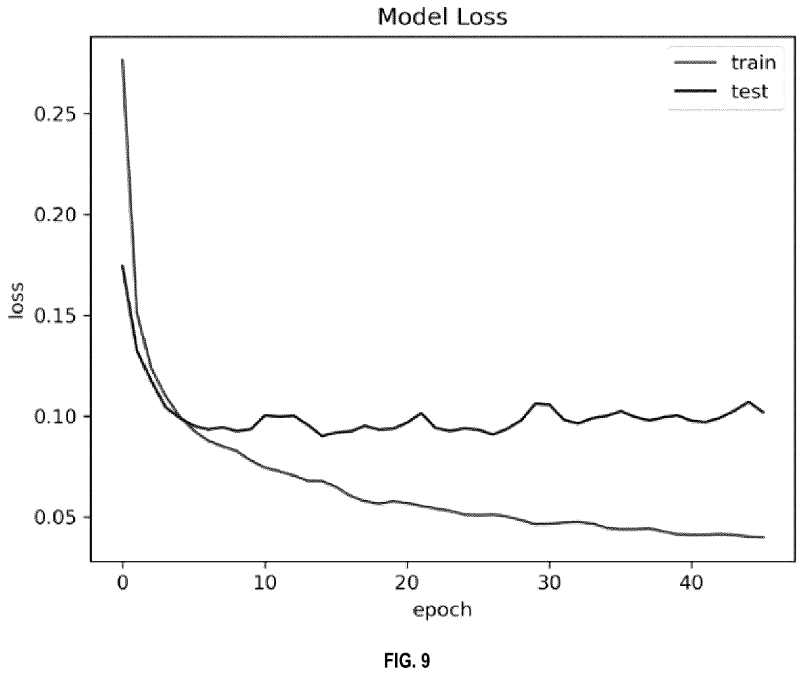

In FIG. 8 depicts a loss history in the training process. FIG. 9 shows deep learning model predictions exhibited by the system 100 with ground truths. The first row represents microstructures of RVEs, and the second and third rows are fracture patterns from LPM simulations and the network, respectively. It can be observed that the prediction has a good agreement with the ground truth. This verifies the predictive ability to make a solid prediction for fracture patterns.

### 4.2 Model Evaluation

It should be noticed that fracture pattern is skewed data that fracture pixels are around 5% of total pixels as we defined, therefore, F1 score is used as an accuracy metric to evaluate the model prediction performance. F1 score is the harmonic mean of the precision and recall, which is suitable for binary skew classification. The precision is the proportion of correct positive predictions, as:

$$precision = \frac{TP}{TP + FP} \qquad ( 13 )$$

where TP is true positives, FP is false positives. The recall is the proportion of true positives which can be predicted, as

$$recall = \frac{TP}{TP + NP} \qquad ( 14 )$$

where NP False negatives. Thus, the expression of F1 score is given as:

$$F 1 = 2 \frac{precision \times recall}{precision + recall} \qquad ( 15 )$$

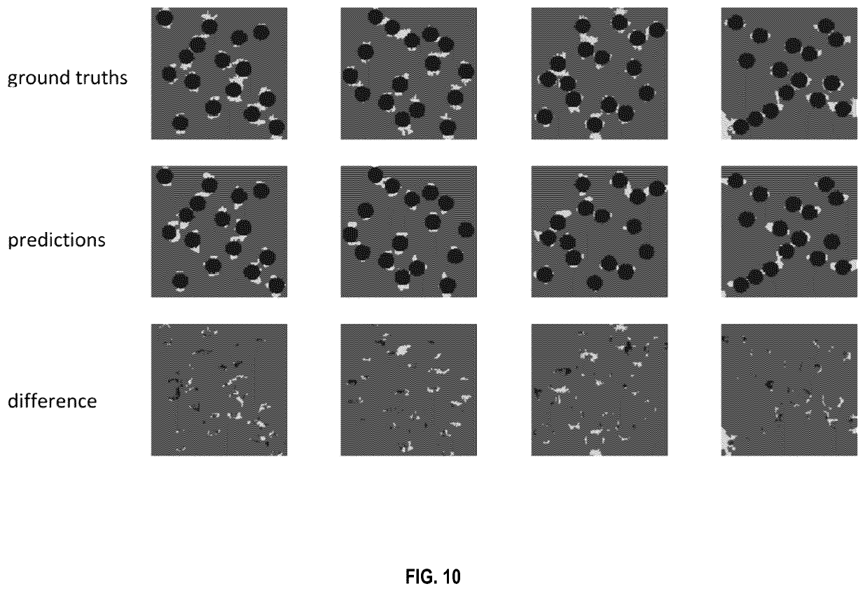

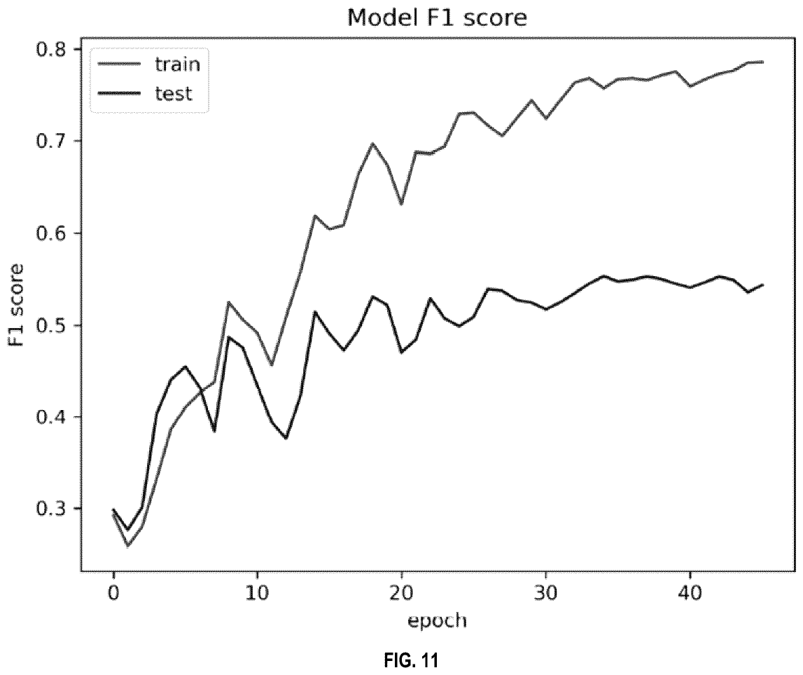

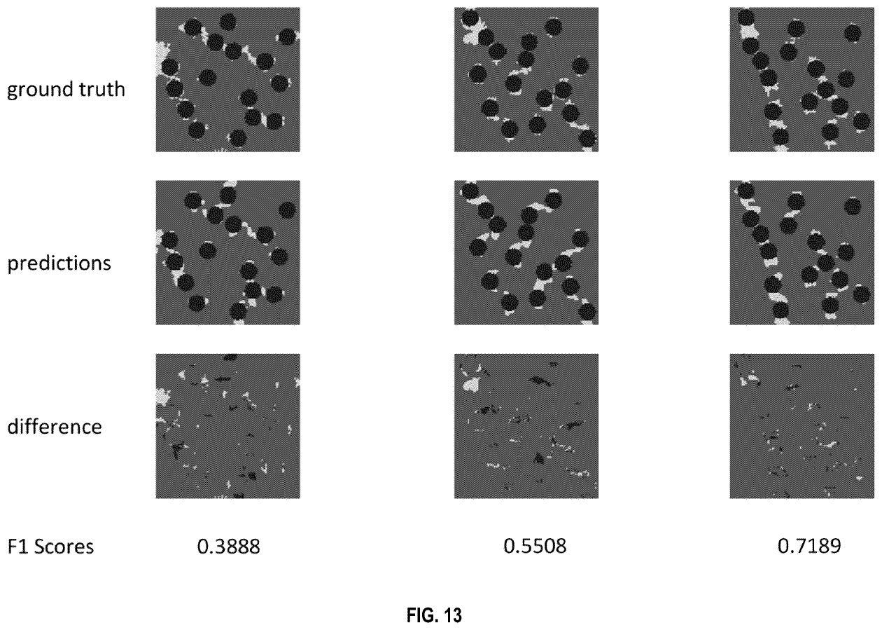

In FIG. 10 shows the F1 score history in the model training process. After tuning the proposed model, the F1 scores for training and testing datasets can reach 0.8 and 0.5, respectively. However, the F1 score metric is not sufficient to evaluate the model performance in this situation, because F1 score metric considers the prediction as a one-dimensional flatten array and ignores spatial information in prediction. To describe this spatial issue of F1 score, a typical example of a two-dimensional array of size 8×8 is used. In FIG. 11, ground truth and two predictions are given. The F1 scores for the two predictions are 0 because both two predictions have no positives correctly predicted. While the left prediction is considered more accurate than the right prediction since the predicted positives in the left prediction are spatially closer to the true positives. Max pooling with a factor of 2 can be adopted to extract the spatial accuracy of the ground truth and two predictions, as shown in FIG. 12. After max pooling, the F1 scores for the left and right predictions are changed to 1 and 0, respectively.

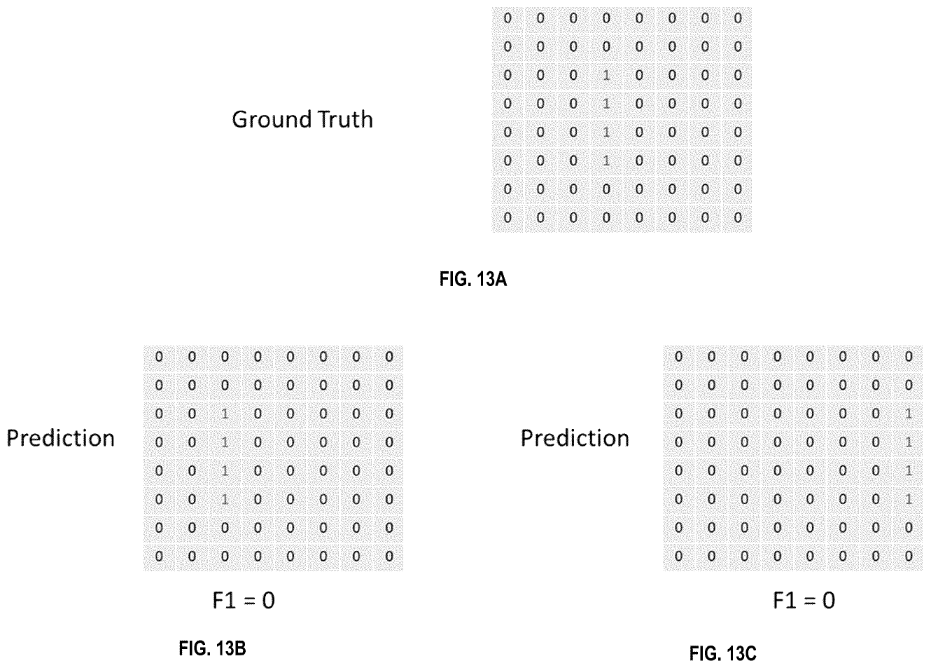

This indicates that the max-pooling operation can be used for spatial accuracy evaluation, and the F1 score is higher with max-pooling if the prediction has better spatial accuracy. Therefore, max pooling is performed for the predictions from the FCN 200 and the ground truths generated by LPM, and then we compare the F1 scores to show the spatial accuracy. The array size is changed from 128×128 to 64×64. It can be seen in FIG. 13, the F1 score is improved to 0.6, which demonstrates the spatial accuracy of the FCN 200.

### 5. Discussions

### 5.1 Comparison Between Physics-Informed Model and Data Driven Model

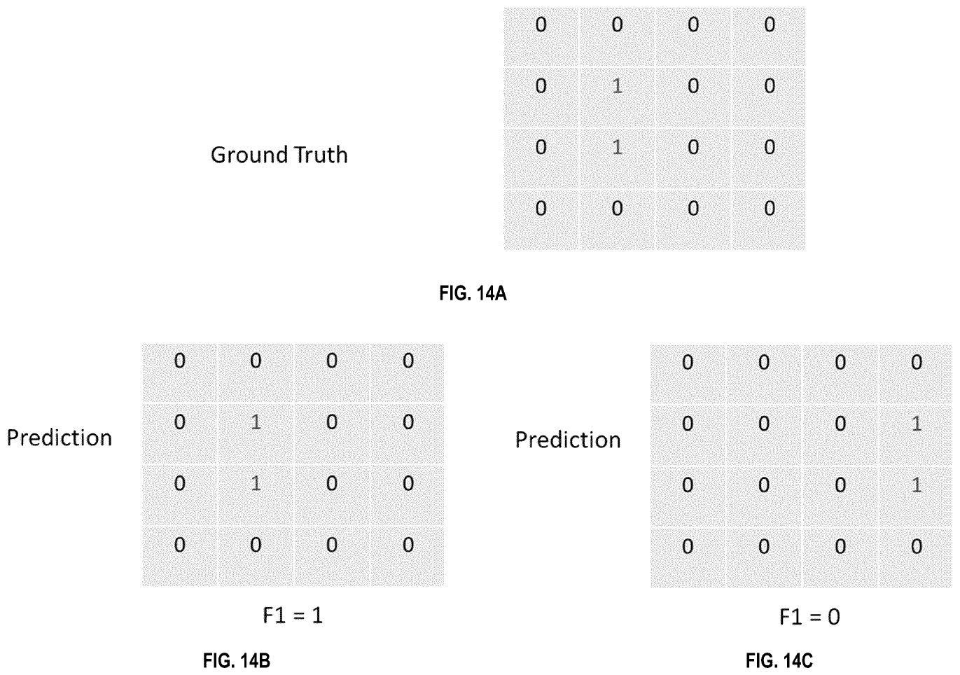

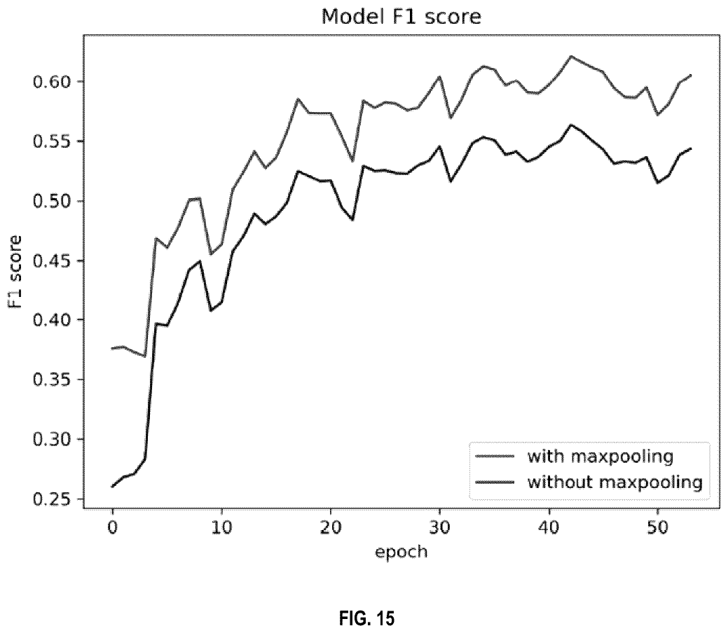

Comparing the data driven model, the elastic deformation, which can be calculated based on the boundary conditions and loading conditions, is taken by the proposed deep learning model as physics knowledge. The data driven model only takes the boundary conditions and loading conditions as the input data. The performance of these two different models is compared to show the power of the physics knowledge. The driven model is similar with the proposed physics-informed model mentioned in Section 3.3, which only replaces the displacement images with loading conditions images in the input channels. The structure of the deep learning model and the activation functions are same with the physics-informed model. The data driven model is tuned using same training data and optimization algorithm. The early stopping approach is also used during the data driven model tuning, which stops the tuning once the testing accuracy metric is smaller than its maximum value over ten epochs. FIG. 14 shows the model loss of the physics-informed model and the data driven model. It is obviously that the loss of the physics-informed model is smaller than the data driven model. F1 score is used for model evaluation. The comparison of F1 scores of these two different models is shown in FIG. 15. It can be seen that the F1 score of the data driven model is too low to be acceptable. On the contrary, the performance of the physics-informed model is much better than the data driven model. The comparison of training loss and F1 scores between the physics-informed model and the data driven model indicates that the physics knowledge in the model improves the model accuracy. The over fitting phenomenon in data driven model tuning is obviously. Thus, data driven model needs more training data and more training time to achieve same prediction accuracy as the proposed physics-informed model.

### 5.2 Effect of Physical Constraint

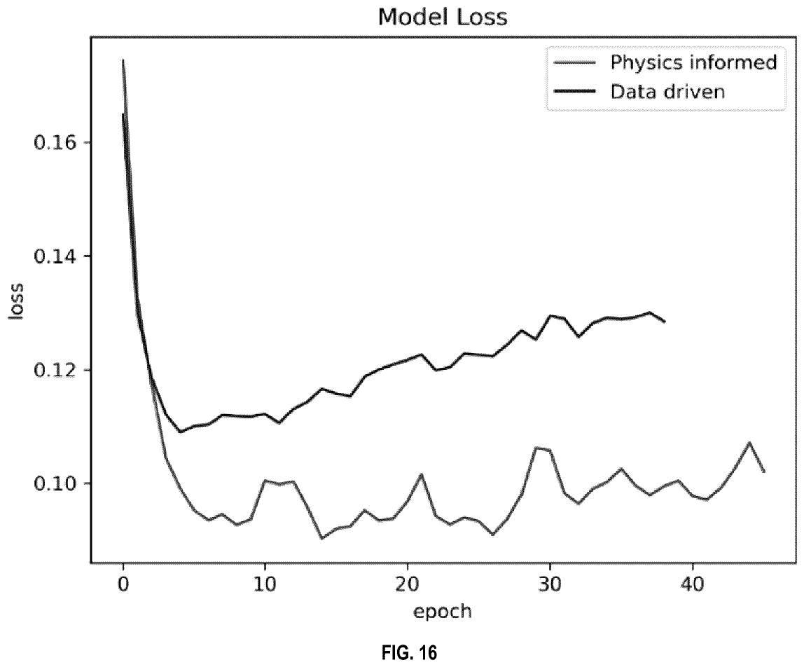

The effect of the physical constraint can be obtained via the accuracy metric, shown in FIG. 16. Comparing the F1 scores with and without the physical constraint, it can be observed that the physical constraint improves the model accuracy and accelerates the tuning process by reducing the model training iterations before overfitting. This work shows that the potential of utilizing physics prior knowledge to help designing neural networks for practical physics problems.

### 5.3 Comparison of Different Loadings

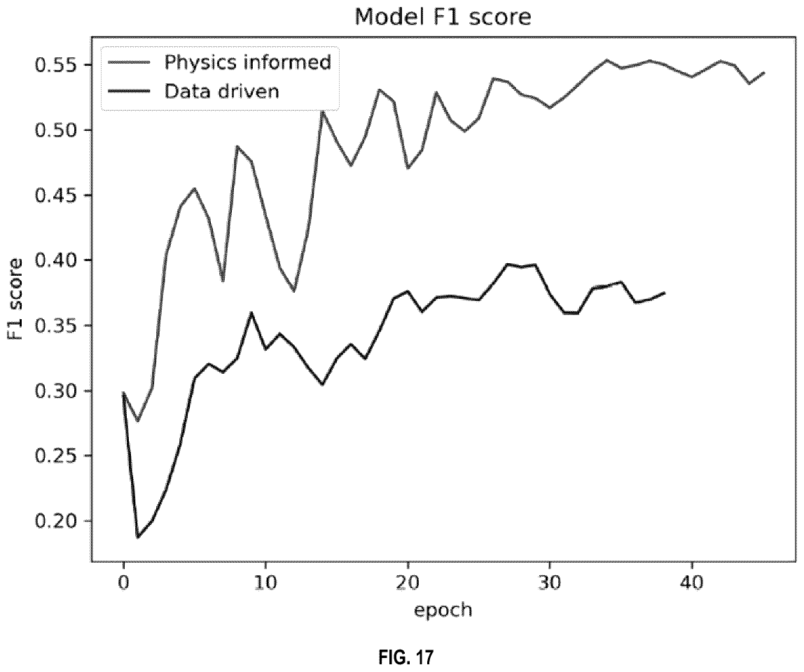

A benchmark is used to verify the predictive power of the proposed model, which has a given arbitrary microstructure under two different loadings. The microstructure is shown in the first row in FIG. 17. The first scenario applies a load on the right surface in the horizontal direction, and the second scenario applies a load on the bottom surface downward. The boundary conditions for the two scenarios are the same that left and top surfaces are clamped in horizontal and vertical directions, respectively, see the second row in FIG. 17. The third and fourth rows in FIG. 17 present the ground truths and the predictions. As expected, the predicted fracture patterns are similar to the ground truths, meanwhile, with the same microstructure, the predicted patterns are different for different loadings. This benchmark demonstrates that the proposed model is able to predict the fracture pattern without limitations of both material microstructure and loading conditions.

### 6. Conclusion

The system 100 provides a physics-informed model to predict fracture patterns under various loading conditions with different microstructures. The framework includes LPM for elastic linear deformation simulation and a deep learning network for nonlinear fracture simulation, which considers both computational accuracy and efficiency. LPM is used to calculate material elastic displacement as the physics inputs for the deep learning model and generate a dataset to tune the deep network. The deep learning model implemented by the system 100 is based on the concept of FCNs. A physical constraint is integrated to improve the deep learning model's predictive performance. The proposed model is evaluated by different microstructures and loading conditions. Several major conclusions are:
The physics-informed model implemented by the system 100 takes advantage of LPM and the deep learning model and can predict fracture patterns efficiently without losing accuracy. Predicted fracture patterns of different microstructures and different loading conditions have good agreement with ground truths;
Comparing with purely data driven model, the system 100 has better predictive performance. Meanwhile, the proposed physics-informed model requires less training data for model tuning;
The deep learning model implemented by the system 100 with a physical constraint has better predictive performance. The applied physical constraint improves the F1 score 10% higher and reduces the iteration number of the model training;
Max-pooling operations demonstrate that the system 100 considers the spatial accuracy of prediction.

The system 100 integrates LPM in this study. It should be mentioned that the deep learning model (e.g., the FCN 200) implemented by the system 100 has the potential to integrating with other mechanics models to predict material fracture patterns. Future work will be toward extending the system 100 to fracture analysis of ductile materials and composite materials, which will require more complex mechanics models. The performance of the deep learning network has the potential to be improved by modifying the network structure with CNNs algorithms, such as ResNet and Feature Pyramid Networks (FPN).

### Computer-Implemented System

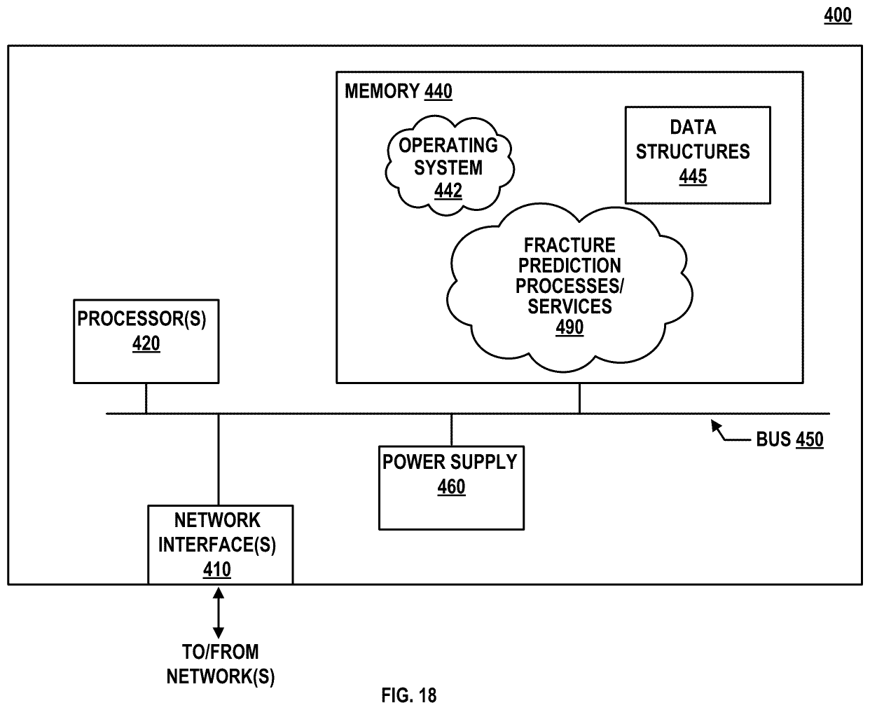

FIG. 18 is a schematic block diagram of an example device 400 that may be used with one or more embodiments described herein, e.g., as a component of system 100 including FCN 200 and implementing aspects of process 300.

Device 400 comprises one or more network interfaces 410 (e.g., wired, wireless, PLC, etc.), at least one processor 420, and a memory 440 interconnected by a system bus 450, as well as a power supply 460 (e.g., battery, plug-in, etc.).

Network interface(s) 410 include the mechanical, electrical, and signaling circuitry for communicating data over the communication links coupled to a communication network. Network interfaces 410 are configured to transmit and/or receive data using a variety of different communication protocols. As illustrated, the box representing network interfaces 410 is shown for simplicity, and it is appreciated that such interfaces may represent different types of network connections such as wireless and wired (physical) connections. Network interfaces 410 are shown separately from power supply 460, however it is appreciated that the interfaces that support PLC protocols may communicate through power supply 460 and/or may be an integral component coupled to power supply 460.

Memory 440 includes a plurality of storage locations that are addressable by processor 420 and network interfaces 410 for storing software programs and data structures associated with the embodiments described herein. In some embodiments, device 400 may have limited memory or no memory (e.g., no memory for storage other than for programs/processes operating on the device and associated caches).

Processor 420 comprises hardware elements or logic adapted to execute the software programs (e.g., instructions) and manipulate data structures 445. An operating system 442, portions of which are typically resident in memory 440 and executed by the processor, functionally organizes device 400 by, inter alia, invoking operations in support of software processes and/or services executing on the device. These software processes and/or services may include fracture prediction processes/services 490 which can include a set of instructions within the memory 440 that implement aspects of process 300 when executed by the processor 420. Note that while fracture prediction processes/services 490 is illustrated in centralized memory 440, alternative embodiments provide for the process to be operated within the network interfaces 410, such as a component of a MAC layer, and/or as part of a distributed computing network environment.

It will be apparent to those skilled in the art that other processor and memory types, including various computer-readable media, may be used to store and execute program instructions pertaining to the techniques described herein. Also, while the description illustrates various processes, it is expressly contemplated that various processes may be embodied as modules or engines configured to operate in accordance with the techniques herein (e.g., according to the functionality of a similar process). In this context, the term module and engine may be interchangeable. In general, the term module or engine refers to model or an organization of interrelated software components/functions. Further, while the fracture prediction processes/services 490 is shown as a standalone process, those skilled in the art will appreciate that this process may be executed as a routine or module within other processes.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A system for modeling a fracture process of a represented microstructure, the system comprising:
a processor in communication with a memory, the memory including instructions, which, when executed, cause the processor to:
access, at the processor, a set of material properties of a represented microstructure, the represented microstructure including a plurality of represented particles;
access, at the processor, a set of boundary conditions of the represented microstructure and a set of applied load characteristics representative of an applied load to be applied to the represented microstructure;
model, at the processor, a linear stage of a fracture process of the represented microstructure using a lattice particle method resulting in a first set of data indicative of linear elastic deformation of the represented microstructure; and
model, at the processor, a non-linear stage of the fracture process of the represented microstructure through application of a fully convolutional network formulated at the processor to the set of material properties of the represented microstructure and the first set of data indicative of linear elastic deformation of the represented microstructure resulting in a probability of fracture failure of the represented microstructure.

2. The system of claim 1, wherein the memory incudes instructions, which, when executed, further cause the processor to:
train, at the processor, the fully convolutional network formulated at the processor to model the non-linear stage of the fracture process of the represented microstructure using a ground truth dataset.

3. The system of claim 1, wherein the memory incudes instructions, which, when executed, further cause the processor to:
generate a ground truth dataset for training of the fully convolutional network using the lattice particle method.

4. The system of claim 3, wherein the memory incudes instructions, which, when executed, further cause the processor to:
model, at the processor, the linear stage of the fracture process of a ground truth microstructure of the ground truth dataset using the lattice particle method; and
model, at the processor, the non-linear stage of the fracture process of the ground truth microstructure using the lattice particle method.

5. The system of claim 1, wherein the memory incudes instructions, which, when executed, further cause the processor to:
(1) determine, at the processor, a set of positions of the plurality of represented particles;
(2) determine, at the processor, a position of a represented particle of the plurality of represented particles;
(3) determine a bond stretch factor of the represented particle of the plurality of represented particles;
(4) solve, at the processor, one or more incremental displacements of the plurality of represented particles resulting from breakage of a bond between a first represented particle and a second represented particle of the plurality of represented particles;
(5) update, at the processor, one or more particle positions of the plurality of represented particles resulting from breakage of the bond between the first represented particle and the second represented particle of the plurality of represented particles; and
(6) iteratively repeat steps (1)-(5) until a percentage of fractured particles exceeds a boundary value, resulting in the first set of data indicative of linear elastic deformation of the represented microstructure.

6. The system of claim 5, wherein the memory incudes instructions, which, when executed, further cause the processor to:
simulate, at the processor, breakage of the bond between the first represented particle and the second represented particle of the plurality of represented particles.

7. The system of claim 1, wherein the memory incudes instructions, which, when executed, further cause the processor to:
represent the first set of data indicative of linear elastic deformation of the represented microstructure as an image; and
receive, at the fully convolutional network implemented at the processor, the image representative of linear elastic deformation of the represented microstructure;
apply, at the fully convolutional network implemented at the processor, a plurality of convolutional layers of the fully convolutional network to extract one or more features of the image; and
apply, at the fully convolutional network implemented at the processor, a plurality of deconvolutional layers of the fully convolutional network to label one or more pixels of the image according to the one or more features of the image.

8. The system of claim 7, wherein the plurality of deconvolutional layers of the fully convolutional network label a plurality of pixels of the image according to a probability of fracture failure of each pixel of the plurality of pixels of the image.

9. The system of claim 8, wherein the memory incudes instructions, which, when executed, further cause the processor to:
apply, following an output layer of the fully convolutional network, one or more constraints that represent one or more pixels within the image in a hole area of the represented microstructure as having a zero probability of fracture failure.

10. The system of claim 1, wherein the processor integrates deep learning and the lattice particle method.

11. The system of claim 10, wherein the processor is implemented to generate training data of data of fracture patterns and elastic deformation by utilizing a fracture criterion implemented in the lattice particle method.

12. A method for modeling a fracture process of a represented microstructure, comprising:
implementing, by a processor, a model material fracture pattern prediction, the model combining a lattice particle method and deep learning, including:
accessing, at the processor, a set of material properties of a represented microstructure, the represented microstructure including a plurality of represented particles;
accessing, at the processor, a set of boundary conditions of the represented microstructure and a set of applied load characteristics representative of an applied load to be applied to the represented microstructure; and
modeling, at the processor, a non-linear stage of the fracture process of the represented microstructure through application of a fully convolutional network formulated at the processor to the set of material properties of the represented microstructure and the first set of data indicative of linear elastic deformation of the represented microstructure resulting in a probability of fracture failure of the represented microstructure.

13. The method of claim 12, further comprising:
training, at the processor, the fully convolutional network formulated at the processor to model the non-linear stage of the fracture process of the represented microstructure using a ground truth dataset.

14. The method of claim 12, wherein the memory incudes instructions, which, when executed, further cause the processor to:
generate a ground truth dataset for training of the fully convolutional network using the lattice particle method.

15. The method of claim 14, further comprising:
modeling, at the processor, the linear stage of the fracture process of a ground truth microstructure of the ground truth dataset using the lattice particle method; and
modeling, at the processor, the non-linear stage of the fracture process of the ground truth microstructure using the lattice particle method.

16. The method of claim 12, further comprising:
(1) determining, at the processor, a set of positions of the plurality of represented particles;
(2) determining, at the processor, a position of a represented particle of the plurality of represented particles;
(3) determining a bond stretch factor of the represented particle of the plurality of represented particles;
(4) computing, at the processor, one or more incremental displacements of the plurality of represented particles resulting from breakage of a bond between a first represented particle and a second represented particle of the plurality of represented particles;
(5) updating, at the processor, one or more particle positions of the plurality of represented particles resulting from breakage of the bond between the first represented particle and the second represented particle of the plurality of represented particles; and
(6) iteratively repeating steps (1)-(5) until a percentage of fractured particles exceeds a boundary value, resulting in the first set of data indicative of linear elastic deformation of the represented microstructure.

17. The system of claim 12, further comprising:
simulating, at the processor, breakage of the bond between the first represented particle and the second represented particle of the plurality of represented particles.

18. A non-transitory, computer-readable medium storing instructions encoded thereon, the instructions, when executed by one or more processors, cause the one or more processors to perform operations to:
access a set of material properties of a microstructure, the set of material properties including heterogeneous random microstructure information; and
model material mechanics of the microstructure including material fracture pattern prediction by application of the set of material properties to a machine learning model, the machine learning model being physics-informed and trained to predict fracture patterns for arbitrary geometries and loading conditions for the microstructure by integrating deep learning and a lattice particle method.

19. The non-transitory, computer-readable medium of claim 18, comprising further instructions encoded thereon, the further instructions, when executed by the one or more processors, cause the one or more processors to perform further operations to:
utilize the lattice particle method to simulate material elastic deformation in a linear stage as input for the deep learning model.

20. The non-transitory, computer-readable medium of claim 18, comprising further instructions encoded thereon, the further instructions, when executed by the one or more processors, cause the one or more processors to perform further operations to:
generate a training dataset of fracture pattern to train the machine learning model.
